(19) United States
(12) Patent Application Publication
(10) Pub. No.: US 2010/0246136 A1
(43) Pub. Date: Sep. 30, 2010

(54) HEAT SINK AND ELECTRONIC DEVICE USING THE SAME

(75) Inventors: FANG-XIANG YU, Shenzhen City (CN); JER-HAUR KUO, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 12/489,426

(22) Filed: Jun. 22, 2009

(30) Foreign Application Priority Data
Mar. 24, 2009 (CN) 200910301089.4

(51) Int. Cl. H05K 7/20; F28F 13/00

(52) U.S. Cl. 361/710; 165/80.3

(57) ABSTRACT

A heat sink includes two heat spreaders spaced from each other and a plurality of heat dissipation fins disposed between the heat spreaders. The heat dissipation fin is curved from one of the heat spreaders to the other one of the heat spreaders. A curved air passage is formed between every two adjacent heat dissipation fins. The heat dissipation fin can resiliently deform to change a distance between the heat spreaders. The present disclosure also discloses an electronic device incorporating such a heat sink. The electronic device comprises a shell and an electronic component mounted in the shell. One of the heat spreaders is attached to the electronic component and the other one is attached to the shell.

### BACKGROUND

1. Technical Field

The present disclosure relates to heat sinks, and particularly to a heat sink having a good adaptability to different electronic devices.

2. Description of Related Art

With continuing development of the electronic technology, electronic components such as CPUs (central processing units) generate more and more heat required to be dissipated immediately. Conventionally, heat sinks are used to remove the heat generated by the electronic components.

A typical heat sink includes a base and a plurality of heat dissipation fins extending upwardly and perpendicularly from the base. The heat dissipation fins are flat-shaped and rigid. A size of the heat sink can not be changed in use unless be destroyed. However, different electronic devices usually have different shapes and sizes, and thus a space of each electronic device for accommodating the heat sink is different from that of other electronic devices. Therefore, the heat sink with a changeless size can only be used in one specifically electronic device, which causes an inferior adaptability to the heat sink.

For the said reasons, a heat sink overcomes the described limitations is desired.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an isometric view of a heat sink according to a first embodiment of the present disclosure.

FIG. 2 is a schematic view of an electronic device incorporating the heat sink of FIG. 1.

FIG. 3 is a front view of a heat sink according to a second embodiment of the present disclosure.

FIG. 4 is an isometric view of a heat sink according to a third embodiment of the present disclosure.

FIG. 5 is an isometric view of a heat sink according to a fourth embodiment of the present disclosure.

### DETAILED DESCRIPTION

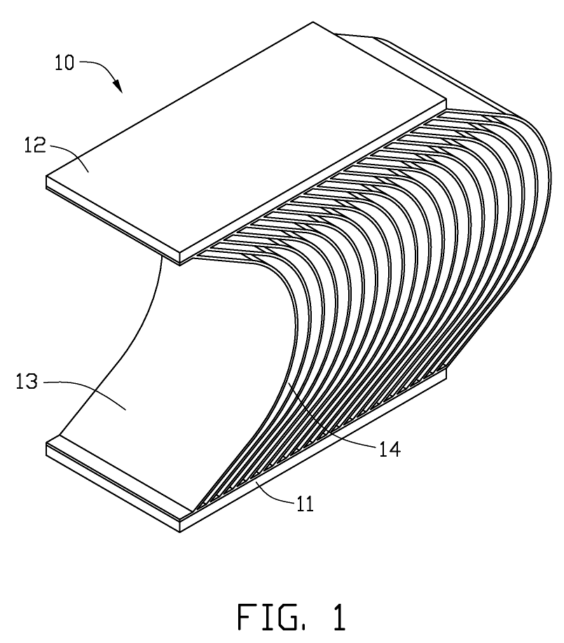

Referring to FIG. 1, a heat sink 10 according to the first embodiment of the present disclosure is shown. The heat sink 10 is made of a material having a good heat conductivity and pliability, such as aluminum or aluminum alloy. The heat sink 10 includes a first heat spreader 11, a second heat spreader 12 spaced from the first heat spreader 11, and a plurality of heat dissipation fins 13 disposed between the first heat spreader 11 and the second heat spreader 12. Preferably, the heat spreaders 11, 12 are integrally formed with the fins 13.

The heat spreaders 11, 12 are identical to each other. Each of the heat spreaders 11, 12 is substantially a rectangular plate. The first heat spreader 11 faces to and is parallel to the second heat spreader 12.

Each of the heat dissipation fins 13 is curved from the first heat spreader 11 to the second heat spreader 12. The heat dissipation fins 13 are curved to the same direction. The heat dissipation fins 13 are parallel to each other and arranged along a horizontal direction, with top ends thereof connecting with the first heat spreader 11 and bottom ends thereof connecting with the second heat spreader 12. A curved air passage 14 is formed between every two adjacent heat dissipation fins 14. The heat dissipation fins 14 can be further stretched or compressed by changing a distance between the heat spreaders 11, 12.

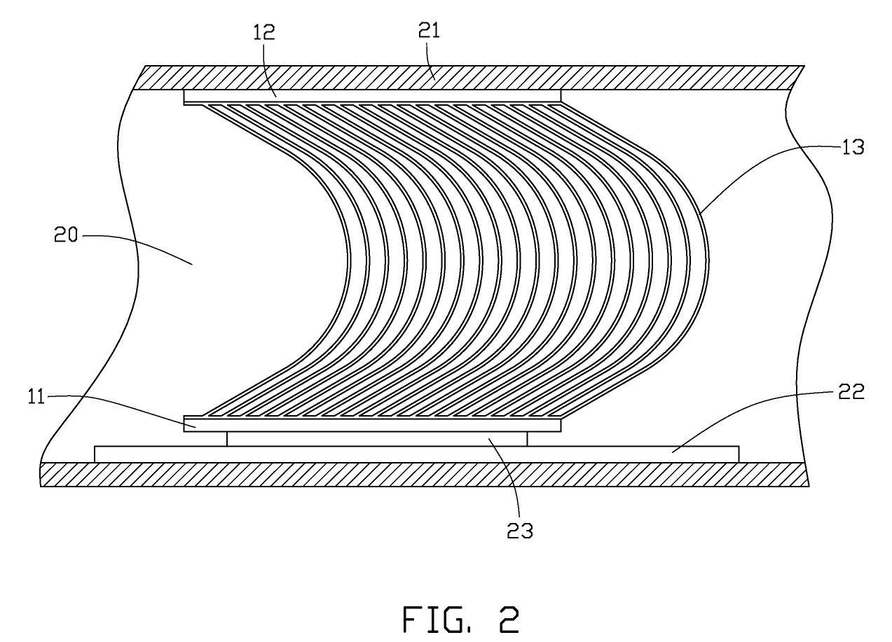

Referring to FIG. 2, an electronic device 20 incorporating the heat sink 10 is shown. The electronic device 20 may be a computer, a projector, etc. In general, the electronic device 20 has a component which generates heat that needs an effective dissipation by a heat sink to ensure that the electronic device 20 can work normally. The electronic device 20 includes a shell 21, a printed circuit board 22 secured on an inner surface of the shell 21, and an electronic component 23 mounted on the printed circuit board 22, such as a CPU, a north bridge, etc. The heat sink 10 is received in the shell 21 and secured on the electronic component 23. The first heat spreader 11 of the heat sink 10 is attached to the electronic component 23 and acts as a heat absorber to absorb the heat of the electronic component 23. In this embodiment, the inner space of the shell 21 is narrow, with a height being a little smaller than that of the heat sink 10 at free. Since the heat dissipation fins 13 can be farther compressed to be further curved resiliently, the heat sink 10 is compressed along a direction perpendicular to the heat spreaders 11, 12 to reduce the height of the heat sink 10, and thus the heat sink 10 can be mounted into the narrow inner space of the electronic device 20. The second heat spreader 12 is resiliently pushed by the deformed heat dissipation fins 13 to abut against an inner surface of the shell 21 at a side opposite to the printed circuit board 22. Thus, the heat of the heat dissipation fins 13 is transferred to the shell 21 by the second heat spreader 12 and then dissipate to ambient air directly, which enables the shell 21 to function as an assistant component for heat dissipation.

Likewise, if the inner space of the shell 21 has a large height, the heat sink 10 may be stretched along the direction perpendicular to the heat spreaders 11, 12 to increase the height of the heat sink 10, thereby to enable the second heat spreader 12 to abut the inner surface of the shell 21 for enhancing heat dissipation efficiency of the heat sink 10. Furthermore, the heat sink 10 abutting the shell 21 of the electronic device 20 can deform when subjected to an external force, thereby to act as a buffer to reduce an impact of the external force on the electronic component 23 when the electronic device 20 suffers an impulsive force or a vibration, thus to protect the electronic component 23 from damage.

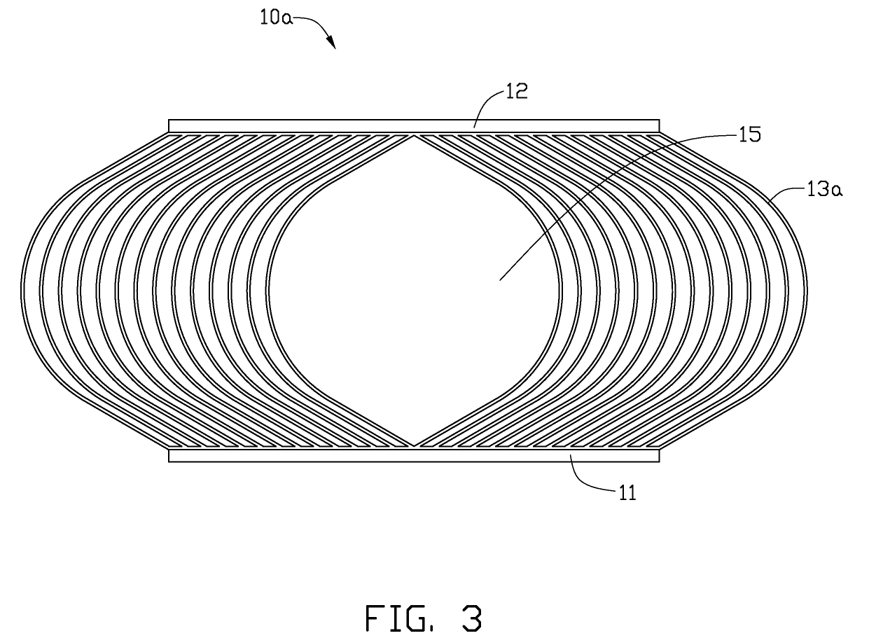

FIG. 3 shows a heat sink 10a according to a second embodiment of the present disclosure, differing from the previous heat sink 10 only in that the heat dissipation fins 13a being evenly divided into two groups. The heat dissipation fins 13a in the same group are curved to the same direction. The heat dissipation fins 13a of the two groups are curved to two opposite directions. Thus an O-shaped cavity 15 is formed between the two groups of the heat dissipation fins 13a of the heat sink 10a.

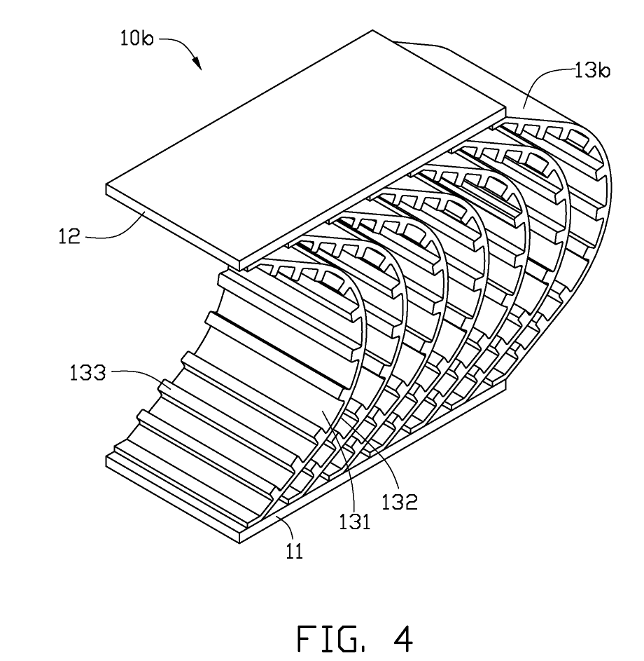

FIG. 4 shows a heat sink 10b according to a third embodiment of the present disclosure. The heat sink 10b is similar to the first embodiment, all of the fins 13b being curved to the same direction. The heat sink 10b differs from the first embodiment in that the heat sink 10b has a plurality of projections 133 formed on each heat dissipation fin 13b. Each of the heat dissipation fins 13b includes a concave surface 131 and a convex surface 132 opposite to the concave surface 131. The projections 133 are bar-shaped and extend outwardly from the concave surface 131 of a heat dissipation fin 13b towards the convex surface 132 of an adjacent heat dissipation fin 13b. A height the projection 133 extending out of the heat dissipation fin 13b is less than a distance between every two adjacent heat dissipation fins 13b, which avoids a collision between the projections 133 and the heat dissipation fins 13b when the heat dissipation fins 13b are deformed with a predetermined range. The projections 133 of each heat dissipation fin 13b are horizontal, and are parallel to the heat spreaders 11, 12, when the fins 13b are stretched to be vertically oriented. A length of each projection 133 is equal to a width of each of the fins 13b. The projections 133 are spaced from each other along a height direction of the heat sink 10b for increasing a heat dissipation area of the heat sink 10b.

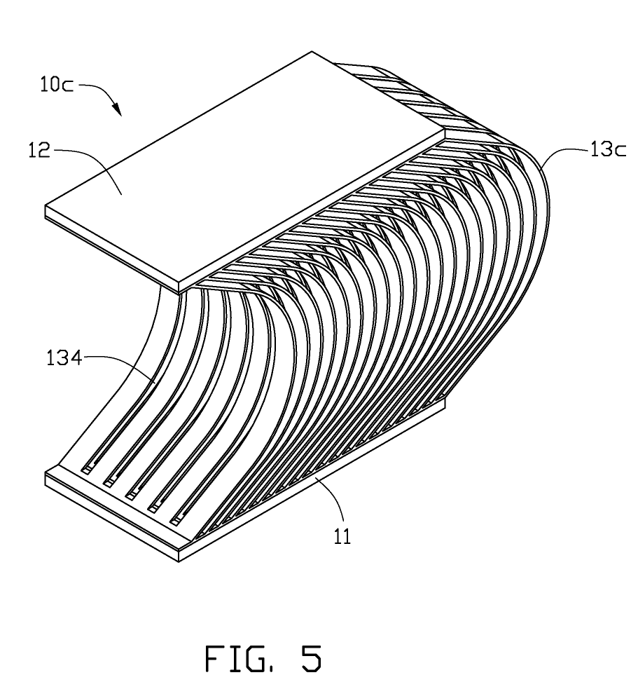

FIG. 5 shows a heat sink 10c according to a fourth embodiment of the present disclosure. The heat sink 10c differs from the first embodiment in that the heat sink 10c defines a plurality of slots 134 in each heat dissipation fin 13c. The slots 134 extend from the first heat spreader 11 to the second heat spreader 12 and divide each heat dissipation fin 13c into a plurality of bar-shaped heat dissipation portions. The slots 134 enforce the deformability of the heat dissipation fins 13c.

It is to be understood that even though numerous characteristics and advantages of the disclosure have been set forth in the foregoing description, together with details of the structure and function of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat sink comprising:
two heat spreaders spaced from each other; and
a plurality of heat dissipation fins disposed between the two heat spreaders, each of the heat dissipation fins being curved from one of the heat spreaders to the other one of the heat spreaders, a curved air passage being formed between every two adjacent heat dissipation fins;
each of the heat dissipation fins can be resiliently deformed by changing a distance between the two heat spreaders.

2. The heat sink of claim 1, wherein the heat dissipation fins are divided into a plurality of groups, the heat dissipation fins in the same group are curved to the same direction, and the heat dissipation fins of different groups are curved to different directions.

3. The heat sink of claim 2, wherein the heat dissipation fins are divided into two groups, the heat dissipation fins of the two groups are curved to two opposite directions, an O-shaped cavity is formed between the two groups of the heat dissipation fins of the heat sink.

4. The heat sink of claim 1, wherein a plurality of projections extends outwardly from each of the heat dissipation fins towards an adjacent fin, a height the projection extending out of the each of the heat dissipation fins is less than a distance between every two adjacent heat dissipation fins.

5. The heat sink of claim 4, wherein the projections are bar-shaped and spaced from each other along a height direction of the heat sink.

6. The heat sink of claim 1, wherein each of heat dissipation fins defines a plurality of slots therein.

7. The heat sink of claim 6, wherein the slots extend from one of the heat spreaders to the other one of the heat spreaders, the slots divide the each of the heat dissipation fins into a plurality of bar-shaped heat dissipation portions.

8. The heat sink of claim 1, wherein the heat spreaders are integrally formed with the heat dissipation fins.

9. An electronic device comprising:
a shell;
an electronic component mounted in the shell; and
a heat sink received in the shell and mounted on the electronic component to absorb heat therefrom, the heat sink comprising two heat spreaders spaced from each other and a plurality of heat dissipation fins disposed between the two heat spreaders, the heat dissipation fins being curved from one of the heat spreaders to the other one of the heat spreaders, a curved air passage being formed between every two adjacent heat dissipation fins, wherein each of the heat dissipation fins can be resiliently deformed by changing a distance between the two heat spreaders; and
one of the heat spreaders being attached to the electronic component and the other one of the heat spreaders being attached to the shell.

10. The electronic device of claim 9, wherein the heat dissipation fins are divided into a plurality of groups, the heat dissipation fins in the same group are curved to the same direction, and the heat dissipation fins of different groups are curved to different directions.

11. The electronic device of claim 10, wherein the heat dissipation fins are divided into two groups, the heat dissipation fins of the two groups are curved to two opposite directions, an O-shaped cavity is formed between the two groups of the heat dissipation fins of the heat sink.

12. The electronic device of claim 9, wherein a plurality of projections extends outwardly from each of the heat dissipation fins towards an adjacent fin, a height the projection extending out of the each of the heat dissipation fins is less than a distance between every two adjacent heat dissipation fins.

13. The electronic device of claim 12, wherein the projections are bar-shaped and parallel to the heat spreaders, and the projections are spaced from each other along a height direction of the heat sink.

14. The electronic device of claim 9, wherein each of the heat dissipation fins defines a plurality of slots therein.

15. The electronic device of claim 14, wherein the slots extends from one of the heat spreaders to the other one of the heat spreaders, and the slots divide the each of the heat dissipation fins into a plurality of bar-shaped heat dissipation portions.

16. The heat sink of claim 9, wherein the heat spreaders are integrally formed with the heat dissipation fins.
